(19) United States
(12) Patent Application Publication
(10) Pub. No.: US 2008/0017935 A1
(43) Pub. Date: Jan. 24, 2008

(54) SEMICONDUCTOR DEVICE HAVING A NONSALICIDE REGION AND METHOD OF FABRICATING THE SAME

(75) Inventor: Tae Woo KIM, Seoul (KR)

Correspondence Address: LOWE HAUPTMAN HAM & BERNER, LLP, 1700 DIAGONAL ROAD, SUITE 300, ALEXANDRIA, VA, 22314, US

(73) Assignee: DONGBU HITEK CO., LTD., Seoul (KR)

(21) Appl. No.: 11/776,713

(22) Filed: Jul. 12, 2007

(30) Foreign Application Priority Data
Jul. 14, 2006 (KR) 10-2006-0066503

(51) Int. Cl. H01L 29/94; H01L 21/311

(52) U.S. Cl. 257/408; 438/585; 438/703; 257/E21.249; 257/E29.345

(57) ABSTRACT

A method of forming a nonsalicide region in a semiconductor device includes depositing silicon oxide and photoresist on a semiconductor substrate to form a salicide prevention layer and a photoresist layer, respectively, patterning the photoresist layer using a photolithography process to partition the salicide prevention layer into a nonsalicide region and a silicide region, reacting a nitrogen gas of a plasma state to the nonsalicide region, depositing metal on the substrate having the nonsalicide region to form a metal layer, removing the metal layer on the nonsalicide region using etchant. The nonsalicide region is formed with a nitric oxide layer when reacting a nitrogen gas of a plasma state, thereby preventing the formation of undercuts during wet etch process.

### FIELD OF THE INVENTION

The present invention relates, in general, to a method of forming a nonsalicide region in a semiconductor device. More particularly, the present invention relates to a semiconductor having a nonsalicide region and a method of fabricating the same, which is capable of blocking the formation of silicide in the nonsalicide region during a salicide process in a MOSFET semiconductor device having a Lightly Doped Drain (LDD) structure.

### BACKGROUND OF THE INVENTION

In general, as the design rule becomes micro due to high integration of semiconductor devices, the width of a transistor gate electrode and the size of a contact are decreased. Accordingly, to overcome an increase in the gate resistance and contact resistance, a salicide process was developed.

The term “salicide” is an abbreviation of “self aligned silicide”. The salicide process refers to a series of processes, in order, to form a MOS transistor, forming a gate electrode, a source/drain, and a LDD spacer, depositing Group VIII metal, such as Ni, Co or Pt, or Ti in order to lower the resistance of the source/drain region and a gate metal line of the transistor device, and performing an annealing process of making silicon react to the metal material and removing the metal that does not react, such as the metal material of regions except for the source/drain and the gate top surface, through a wet etch process, etc.

The gate, the source, the drain and the like formed on a semiconductor substrate are implemented in a salicide region because they require a low resistance, whereas elements such as resistors are implemented in a nonsalicide region because they require a high sheet resistance.

The conventional salicide and nonsalicide regions are generally implemented through a wet etch process, and are described below.

FIGS. 1a to 1c are cross-sectional views illustrating a conventional method of forming a nonsalicide region.

Referring to FIG. 1a, a salicide prevention layer 20 is deposited on a semiconductor substrate 10. A photolithography process is performed to pattern a nonsalicide region. The salicide prevention layer 20 is generally formed from a silicon oxide layer by a Plasma Enhanced Chemical Vapor Deposition (PE-CVD) method.

As shown in FIG. 1b, a wet etch process is performed to etch the salicide prevention layer 20. In general, an etchant is used to remove the silicon oxide layer and includes a Buffered Oxide Etchant (BOE).

A removal process for a photoresist layer and a post-cleaning process are then performed. A metal layer (not shown) is then deposited and annealed in order to facilitate a silicide reaction. In general, the metal layer preferably includes Ni, Co, Pt, Ti or the like. When Ti is used, an annealing temperature is about 750 degree Celsius.

The metal layer that does not react to silicon is removed by a wet etch method. Accordingly, silicide 40 is not formed in the nonsalicide region, but is formed in the salicide region, as shown in FIG. 1c.

However, the wet etch method induces undercuts at the bottom edges of the photoresist layer owing to the property of isotropic etch, as shown in FIG. 1b.

The undercut regions cause pattern failure since the silicide is formed in subsequent processes for a metal deposition and an annealing, and also degrades device characteristics, such as a leakage current. Accordingly, there are problems in that the yield is decreased and reliability is lowered.

FIG. 2a is a SEM photograph showing undercuts formed at the bottom edges of the photoresist layer due to isotropic etch, and FIG. 2b is a plan SEM photograph showing nonsalicide regions. From FIG. 2b, it can be seen that silicide is irregularly formed at the edges of the nonsalicide regions.

### SUMMARY OF THE INVENTION

It is, therefore, an object of the present invention to provide a method of forming a nonsalicide region of a semiconductor device, which is capable of removing a pattern failure in a subsequent salicide process by preventing undercuts in a nonsalicide wet etch process, thereby improving device characteristics and reliability.

In accordance with an aspect of the present invention, there is provided a method of forming a nonsalicide region in a semiconductor device, comprising:

depositing a silicon oxide layer on a semiconductor substrate and then performing a photolithography process to pattern a nonsalicide region;

making a nitrogen gas of a plasma state react to the silicon oxide layer, and then removing a photoresist layer;

performing wet etch to remove a salicide prevention layer, depositing metal, and performing annealing; and

removing metal that has not reacted to the silicon oxide layer.

In accordance with another aspect of the present invention, there is provided a method of forming a nonsalicide region in a semiconductor device, comprising:

depositing silicon oxide and photoresist on a semiconductor substrate to form a salicide prevention layer and a photoresist layer, respectively;

patterning the photoresist layer using a photolithography process to partition the salicide prevention layer into a nonsalicide region and a silicide region;

reacting a nitrogen gas of a plasma state to the nonsalicide region, and then removing a remaining photoresist layer;

depositing metal on the substrate having the nonsalicide region to form a metal layer; and

removing the metal layer on the nonsalicide region using etchant.

In accordance with further another aspect of the present invention, there is provided a semiconductor device having a nonsalicide region therein fabricated by the method comprising the steps of:

depositing silicon oxide and photoresist on a semiconductor substrate to form a salicide prevention layer and a photoresist layer, respectively;

patterning the photoresist layer using a photolithography process to partition the salicide prevention layer into a nonsalicide region and a silicide region;

reacting a nitrogen gas of a plasma state to the nonsalicide region, and then removing a remaining photoresist layer;

depositing metal on the substrate having the nonsalicide region to form a metal layer; and

removing the metal layer on the nonsalicide region using etchant.

### BRIEF DESCRIPTION OF THE DRAWINGS

The above and other objects and features of the present invention will become apparent from the following description of specific embodiments given in conjunction with the accompanying drawings, in which:

FIGS. 1a to 1c are cross-sectional views illustrating a conventional method of forming a nonsalicide region;

FIG. 2a is a SEM photograph showing undercuts formed by the conventional nonsalicide region formation method;

FIG. 2b is a SEM photograph showing silcide, which is irregularly formed by the conventional nonsalicide region formation method; and

FIGS. 3a to 3d are cross-sectional views illustrating a method of forming a nonsalicide region of a semiconductor device in accordance with the present invention.

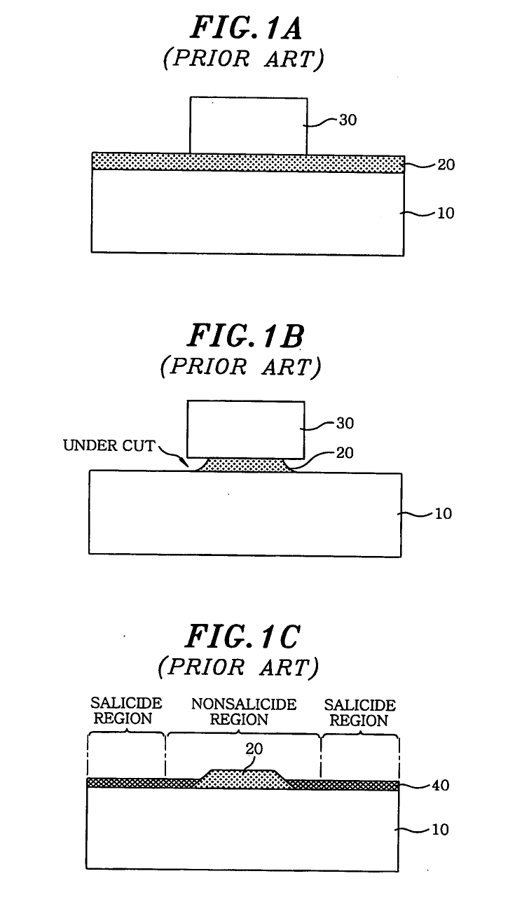

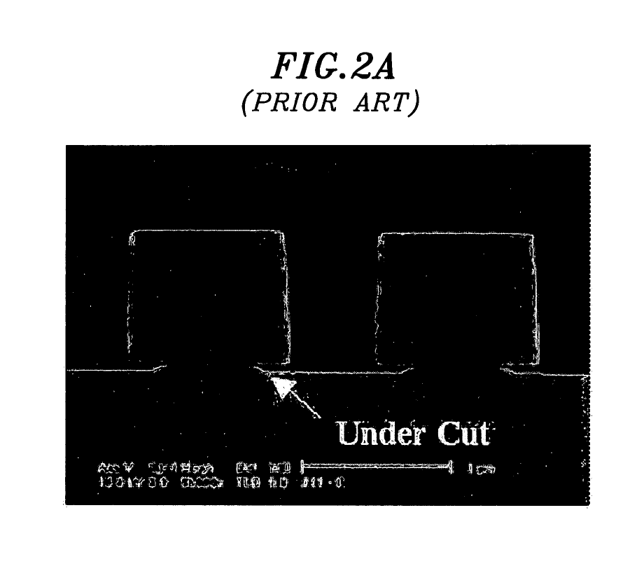

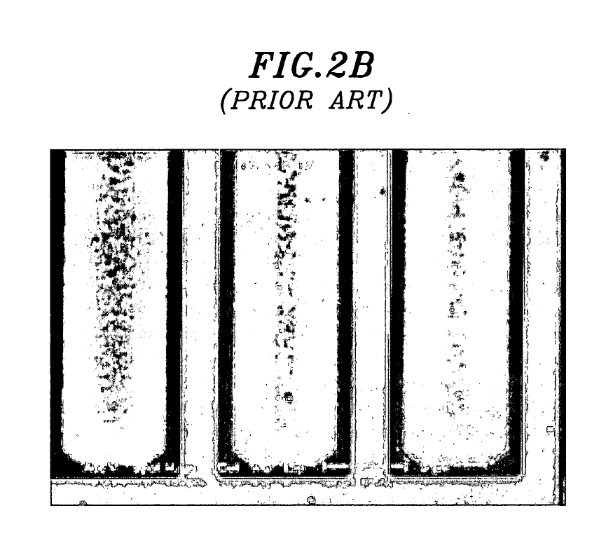

### DETAILED DESCRIPTION OF THE EMBODIMENTS

Hereinafter, embodiments of the present invention will be described in detail with reference to the accompanying drawings so that they can be readily understood by those skilled in the art.

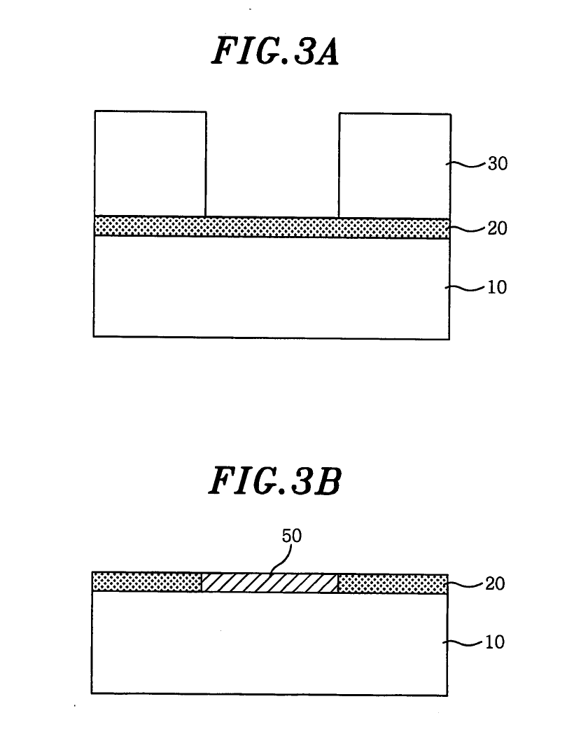

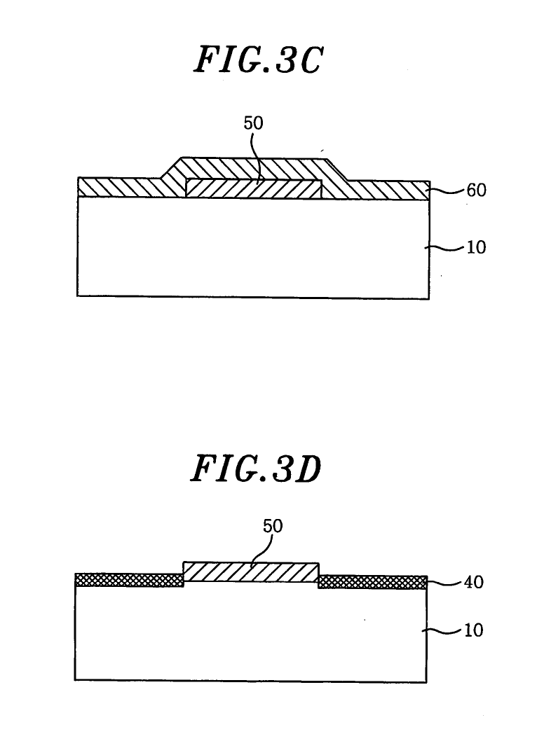

Referring to FIGS. 3a to 3d, there is shown cross-sectional views illustrating a method of forming a nonsalicide region of a semiconductor device in accordance with an embodiment of the present invention.

The method includes a first step, a second step, a third step, and a fourth step as described below.

As shown in FIG. 3a, in the first step, a salicide prevention layer 20, such as a silicon oxide layer, is deposited on a semiconductor substrate 10 by a PECVD method.

After depositing a photoresist layer 30, a photolithography process is then performed to pattern a nonsalicide region. The silicon oxide layer may be deposited to a thickness of 500 to 1000 angstrom. Further, the photoresist layer 30 defined by the photolithography process is patterned by a method of opening the nonsalicide region unlike the prior art. That is, the nonsalicide region is exposed through the photolithography process. Therefore, the salicide prevention layer 20 is divided into the silicide region and the nonsalicide region.

Next, as shown in FIG. 3b, in the second step, a nitrogen gas of a plasma state reacts to the silicon oxide layer in dry etch equipment. The photoresist layer is then removed. More specifically, a plasma is formed by using an argon (Ar) gas and a nitrogen (N) gas as major gases in a plasma etch apparatus. The ionized nitrogen gas reacts to the silicon oxide layer of the nonsalicide region thus opened to form a nitride oxide layer 50.

Subsequently, as shown in FIG. 3c, in the third step, a wet etch process is performed to remove the salicide prevention layer 20. A metal layer 60 is then deposited and annealed. More specifically, the silicon oxide layer, that is, the salicide prevention layer 20 existing in the salicide region is removed through reaction with an etchant. The nitride oxide layer 50 existing in the nonsalicide region is rarely etched in the etchant since it has a low etch rate. In this regard, the ratio of the etch rate between the nitride oxide layer 50 and the silicon oxide layer is approximately 1:7.

Thereafter, a cleaning process, a metal deposition process, and an annealing process are sequentially performed to thereby form silicide, as shown in FIG. 3d. In this case, metal such as Ni, Co, Pt, Ti or the like may be employed during these processes. When Ti is used, an annealing temperature may be about 750 degree Celsius.

In the fourth step, the metal layer 60 that has not reacted with the etchant in the third step is removed. The nitride oxide layer 50 existing in the nonsalicide region serves to hinder the reaction between the silicon substrate 10 and the metal layer 60. Therefore, an etchant is used to remove the metal layer 60 existing in the nitride oxide layer 50.

In the first step as set forth above, it is preferable that the photolithography process include performing patterning by using a negative photoresist. Therefore, a reverse pattern, which is opposite to that of the prior art, can be formed by using a negative photoresist layer 30 without any cost for additional reticle.

As described above, in accordance with the present invention, the nonsalicide region is formed to a nitric oxide layer when reacting a nitrogen gas of a plasma state, thereby preventing the formation of undercuts during a nonsalicide wet etch process. Accordingly, there are advantages in that pattern failure can be prevented in a subsequent salicide process and device characteristics and reliability can be improved.

While the invention has been shown and described with respect to the specific embodiments, it will be understood by those skilled in the art that various changes and modifications may be made without departing from the scope of the invention as defined in the following claims.

What is claimed is:

1. A method of forming a nonsalicide region in a semiconductor device, comprising:
depositing a silicon oxide layer on a semiconductor substrate;
performing a photolithography process to pattern a nonsalicide region;
making a nitrogen gas of a plasma state react with the silicon oxide layer;
removing a photoresist layer;
performing wet etch to remove a salicide prevention layer; depositing metal, and performing annealing; and
removing metal that has not reacted to the silicon oxide layer.

2. A method of forming a nonsalicide region in a semiconductor device, comprising:
depositing silicon oxide and photoresist on a semiconductor substrate to form a salicide prevention layer and a photoresist layer, respectively;
patterning the photoresist layer using a photolithography process to partition the salicide prevention layer into a nonsalicide region and a silicide region;
reacting a nitrogen gas of a plasma state with the nonsalicide region, and then removing a remaining photoresist layer;
salicide prevention depositing metal on the substrate having the nonsalicide region to form a metal layer; and
removing the metal layer on the nonsalicide region.

3. The method of claim 2, wherein the nonsalicide region is formed to a nitric oxide layer when reacting a nitrogen gas of a plasma state.

4. The method of claim 3, wherein wet etch rate between the nitric oxide layer and the silicide region is about 1:7.

5. The method of claim 2, further comprising:
performing wet etch to remove the salicide prevention layer of the silicide region, before depositing metal on the substrate; and
annealing the substrate, after depositing metal on the substrate.

6. The method of claim 2, wherein the photoresist includes a negative photoresist to expose the nonsalicide region.

7. A semiconductor device having a nonsalicide region therein fabricated by the method comprising the steps of:
depositing silicon oxide and photoresist on a semiconductor substrate to form a salicide prevention layer and a photoresist layer, respectively;
patterning the photoresist layer using a photolithography process to partition the salicide prevention layer into a nonsalicide region and a silicide region;
reacting a nitrogen gas of a plasma state to the nonsalicide region;
removing a remaining photoresist layer;
depositing metal on the substrate having the nonsalicide region to form a metal layer; and
removing the metal layer on the nonsalicide region using etchant.

8. The semiconductor device of claim 7, wherein the nonsalicide region is formed to a nitric oxide layer when reacting a nitrogen gas of a plasma state.
